(19) United States
(12) Patent Application Publication
(10) Pub. No.: US 2009/0110847 A1
(43) Pub. Date: Apr. 30, 2009

(54) Apparatus and Method for Producing Light-Emitting Elements With Organic Compounds

(75) Inventor: Jorg Amelung, Dresden (DE)

Correspondence Address: WEINGARTEN, SCHURGIN, GAGNEBIN & LEBOVICI LLP, TEN POST OFFICE SQUARE, BOSTON, MA, 02109, US

(73) Assignee: Fraunhofer-Gesellschaft zur Forderung der angewandten Forschung e. V., Munich (DE)

(21) Appl. No.: 12/084,663

(22) PCT Filed: Nov. 3, 2006
(86) PCT No.: PCT/DE2006/001952

§ 371 Date: May 7, 2008

(30) Foreign Application Priority Data
Nov. 9, 2005 (DE) 10 2005 054 609.9

(51) Int. Cl. C23C 16/00; H05H 1/24

(52) U.S. Cl. 427/569; 118/720

(57) ABSTRACT

The invention relates to an apparatus and a method for the manufacture of light emitting elements comprising organic compounds. These elements are provided with organic light emitting diodes and can be displays or also lighting elements having such light emitting diodes. It is the object of the invention to reduce the effort for the manufacture with respect to the costs and to the time effort. In this connection, already pretreated substrates are further processed in a continuous vacuum coating plant. An electrode is formed on such a substrate and at least one layer of an organic compound which is suitable for the emission of light should be deposited over said electrode. The deposition should take place with different angular distributions. Shadow masks are used for this purpose. The adaptation of the angular distribution in the deposition can take place by varying the spacing of the shadow mask from the substrate and/or of the base pressure of sources for the deposition of the top electrode and of the organic layer(s).

The invention relates to an apparatus and a method for the manufacture of light emitting elements comprising organic compounds. These elements are provided with organic light emitting diodes and can be displays or also lighting elements having such light emitting diodes.

In this connection, light can be emitted with different wavelengths, that is in different colors or also only light in one color can be emitted.

As is known, such elements having organic light emitting diodes (OLEDs) are manufactured by an areal deposition on different substrates. Layers of organic compounds are contained in the layer design which are suitable for the emission of light by an activation by means of an applied electrical voltage.

In this connection, individual light emitting elements are formed on a substrate which are usually called pixels. In this connection, the same or also different organic compounds suitable for the emission of light can be used.

A pattern and a suitable layer design must be taken into account in the manufacture. For this purpose, installation engineering and techniques of thin film technology known per se are used. Elements of relatively small size have previously been used as sub-displays. It is to be assumed that the areas of application of organic light emitting diodes will continue to increase and will increasingly be used for considerably larger displays or lighting elements.

The elements are manufactured with a pattern and a layer design in a vacuum by evaporation of suitable substances and chemical compounds. In this connection, shadow masks are used for the areal patterns through whose openings the gaseous compounds or substances impact a surface with local differentiation and form a layer in a locally bounded manner whose layer thickness can be preset. In this connection, problems occur with the simultaneous pattern application on larger areas since large shadow masks tend to deform. In addition, openings of shadow masks are filled in with the chemical compounds or also substances after more or less long periods of use, up to clogging. A correspondingly frequent cleaning or replacement is therefore necessary. This has a particularly disadvantageous effect in vacuum technology and interruptions in production occur.

Individual light emitting elements on a substrate, however, have to be formed discretely to enable a separate control or to avoid an overlap of different colors of adjacent light emitting elements.

The use of shadow masks is described in U.S. Pat. No. 6,811,808 B2 with which a pattern should be formed on substrates for multicolor displays. In this connection, layers of organic compounds for light with a red, green and blue color should be deposited onto electrodes designed in a structured form on a substrate. For this purpose, a shadow mask with openings is moved stepwise and the openings are positioned in this process. In this connection, the deposition of the gaseous organic compounds takes place with a larger deposition or scattering angle than is the case with a subsequent deposition of further layers with which, for example, a further electrode can also be formed above the layers formed from organic compounds.

In this connection, a further differently patterned shadow mask is used for this/these upper layer(s).

In addition, the elements in question are evaporation coated by means of point sources arranged around a central chamber. This has a plurality of disadvantages since an increased time effort is required for the handling of the substrates. In addition, a large portion of the evaporated organic compounds is lost since they are deposited inside the vacuum chamber and a large portion is sucked out of the vacuum chamber.

The time required can be reduced in continuous vacuum coating plants. However, a time consuming and/or costly replacement of shadow masks within the plant is necessary, which in particular relates to the observation of the vacuum conditions and the required highly precise adjustment of the shadow masks. Particles are liberated by the required movements on the adjustment which reduce the yield in production.

It is therefore the object of the invention to reduce the effort for the manufacture with respect to costs and to time effort.

This object is solved in accordance with the invention by an apparatus having the features of claim 1. The manufacturing process in accordance with the invention is presented in claim 10.

Advantageous aspects and further developments of the invention can be achieved using the features designated in the subordinate claims.

In the invention, already pretreated substrates are processed in a vacuum coating plant. At least one electrode is thus already formed on a suitable substrate and at least one layer of an organic compound which is suitable for the emission of light, e.g. as a consequence of electroluminescence, should be deposited over it.

Different angular distributions are selected for the deposition of organic layers and for the deposition for the forming of top electrodes. In this connection, the angular distribution is wider for the deposition for the forming of top electrodes.

For this purpose, at least one source is present with which the respective organic compound should be transformed into the gas phase. The gaseous organic compound moves through at least one opening of a shadow mask to the surface and there forms a layer in the form of a pixel in a locally bounded manner. The gas flow takes place at a very low scattering angle or depositing angle and is aligned at least almost orthogonally with respect to the surface of the substrate. A very small undercut thereby occurs in the deposition.

The substrate and the same mask are positioned with respect to at least one further source on the translatory movement through the continuous vacuum coating plant. A substance, for example an electrically conductive metal, is transformed into the gas phase by means of this/these further source(s) and is directed through one or more opening(s) of the same shadow mask onto the surface region(s) provided with the organic layer(s) and a top electrode is formed there.

In this connection, the gas flow is directed at a larger scattering angle or depositing angle, e.g. in the form of a conically formed gas flow, onto the respective surface region such that a larger undercut of the shadow mask and a top electrode surface enlarged with respect to the surface coated with organic compound are achieved.

This can be achieved in two alternatives which can, however, also be applied together.

The spacing between the substrate and the shadow mask on the forming of the top electrode(s) can thus, on the one hand, be larger than on the forming of organic layers. This spacing change can be carried out during the transport of the substrate provided with organic layer(s).

There is the possibility as a second alternative to use sources for the forming of the top electrode(s) which have a higher base pressure with respect to sources which can be used for the forming of organic layers.

A wider angular distribution can also be achieved by means of tilted sources. In this connection, at least one source is aligned at an obliquely inclined angle with respect to the substrate surface on which a coating should be formed such that the gas flow discharged from a source tilted in this manner has a central axis correspondingly inclined at an angle with respect to the substrate surface.

An analogous effect can also be achieved with at least one pivotable source. In this connection, the pivoting can take place around an axis or also around a point. The gas flow is then directed through an opening of the shadow mask for the coating in dependence on the respective pivot angle and the top electrode is thereby formed.

Thermal evaporation sources can be used for the forming of organic layers.

Such sources can also be used for the forming of top electrodes. However, CVD sources, and particularly preferably PVD sources, should in particular be used under the aspect of the preferably desired increased base pressure. A magnetron sputter source is an example for this.

All suitable organic compounds can be used for the forming of organic layers. This also applies to the substances used for the forming of top electrodes. The respectively desired layer thicknesses of the individual layers can likewise be observed in a known manner, for example by means of presettable coating times or a presettable speed of the translatory movement.

Large-area substrates can be processed using the invention and a plurality of light emitting elements arranged discretely with respect to one another can be formed on the substrate.

A change of shadow masks during the processing procedure can be dispensed with in an extremely advantageous manner using the invention. This results in a considerable simplification of the process and in an increase in yield. The particle density occurring on the deposition can be reduced.

An on-site contact of top electrodes can be achieved by the increased undercut in the formation of top electrodes.

The invention will be explained in more detail by way of example in the following.

There are shown:

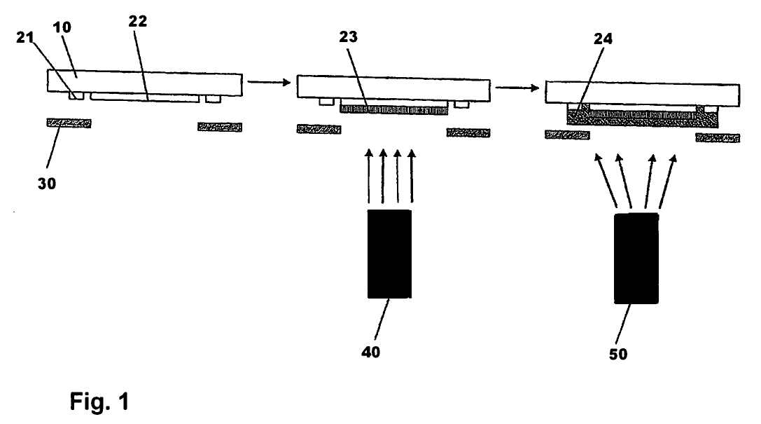

FIG. 1

An example of the invention in schematic form.

A substrate 10 is moved in a translatory manner, as indicated by the arrows, through a continuous vacuum coating plant which is not shown. The substrate 10 has already been patterned with bottom electrodes 21 and 22 separate from one another. The shadow mask 30, with one opening shown here which is positioned with respect to the region of the substrate 10 provided with the bottom electrodes 21 and 22, is moved together with the substrate 10. In this connection, no relative movement takes place between the substrate 10 and the shadow mask 30 in the direction of the translatory movement. The substrate 10 and the shadow mask 30 then move into the area of influence of sources 40. Gaseous organic compounds for the forming of organic layers 23 are directed from the sources 40 onto the surface of the substrate 10 through the opening of the shadow mask 30. In this connection, a plurality of such layers 23 can be formed over one another and at least one layer is formed from an organic compound suitable for the emission of light.

In this connection, the gas flow is directed with a narrow angular distribution at least almost orthogonally to the surface and only expands slightly, if at all, in the direction of the substrate 10.

After completion of the organic layers 23, the substrate 10 and the shadow mask 30 reach the area of influence of further sources 50 with which the forming of a top electrode 24 on the organic layers 23 can be realized. In this connection, a metal or a metal alloy, e.g. aluminum, is transformed into the gas phase by means of the sources 50 and the deposition takes place with a wider angular distribution with respect to the deposition of organic layers 23 described above and a larger undercut of the shadow mask 30 and a coating over a larger area can be achieved using said wider angular distribution. The top electrode 24 formed in this manner is electrically conductively connected to the bottom electrode 21, as can be seen from the right hand representation of FIG. 1. The light emitting element can be controlled via the bottom electrodes 21 and 22.

The sources 40 can be designed as thermal evaporation sources.

The sources 50 can be PVD sources or also CVD sources, such as magnetron sputtering sources.

In this connection, at least one of the sources 50 should be tilted, that is aligned at an oblique angle, with respect to the surface to be coated. This base pressure and/or, optionally, an increased base pressure of sources 50 in comparison with the base pressure of the sources 40 results in a wider angular distribution and larger undercutting of the shadow mask 30 on the deposition and forming of the top electrode 24.

This can also be achieved in a form not shown here by an enlarging of the spacing between the substrate 10 and the shadow mask 30 in the forming of top electrodes 24. In this connection, the respective spacing change can be selected, while taking account of the clearance of openings in the shadow mask 30, of the spacing of the sources 40 and 50 with respect to surface to be coated and to the desired areal sizes to be coated.

1. An apparatus for the manufacture of light emitting elements comprising organic compounds inside a continuous vacuum coating plant with which elements at least one bottom electrode, at least one layer of an organic compound suitable for the emission of light and a top electrode are formed in a locally defined manner on a substrate, with at least one source for the forming of one or more organic layer(s), a shadow mask and at least one further source for the forming of the top electrode(s) being arranged inside the continuous vacuum coating plant, characterized in that evaporated organic compound(s) is/are directed through at least one opening in the shadow mask with a smaller scattering angle in the direction of the substrate than a substance which forms the top electrode and which is guided through the same shadow mask onto the already formed organic layer(s).

2. An apparatus in accordance with claim 1, characterized in that the spacing of the shadow mask from the substrate is larger on the forming of the top electrode than on the forming of organic layers.

3. An apparatus in accordance with claim 1, characterized in that the source(s) for the deposition of the top electrode has/have a higher base pressure than the base pressure of at least one source for the forming of organic layers.

4. An apparatus in accordance with claim 1, characterized in that the substrate and the shadow mask are guided in a translatory manner through a continuous vacuum coating plant in which one or more source(s) for the forming of top electrodes is/are arranged sequentially in the direction of movement at one or more source(s) for organic layer(s).

5. An apparatus in accordance with claim 1, characterized in that the spacing between the substrate and the shadow mask is variable on the translatory movement.

6. An apparatus in accordance with claim 1, characterized in that evaporated organic compounds are directed at least almost orthogonally through the shadow mask onto the substrate.

7. An apparatus in accordance with claim 1, characterized in that at least one tilted or pivotable source for the forming of top electrode(s) is provided.

8. An apparatus in accordance with claim 1, characterized in that the source(s) for the forming of the top electrode is/are a thermal evaporator source, a PVD source and/or a CVD source.

9. An apparatus in accordance with claim 1, characterized in that the at least one source for the forming of organic layer(s) is a thermal evaporator source.

10. A method of manufacturing light emitting elements comprising organic compounds inside a continuous vacuum coating plant, wherein a substrate having base electrode(s) formed on a surface is moved in a translatory manner through a vacuum plant together with a shadow mask;
with at least one gaseous organic compound suitable for the emission of light for the forming of at least one organic layer being directed from at least one source through at least one opening of the shadow mask onto a surface area of the substrate provided with base electrode(s) and having a smaller scattering angle and a smaller undercut than subsequently a gaseous substance for the forming of a top electrode from at least one source through the same opening(s) of the shadow mask onto the one or more organic layer(s).

11. A method in accordance with claim 10, characterized in that the spacing of the shadow mask from the substrate is enlarged on the subsequent forming of the top electrode.

12. A method in accordance with claim 10, characterized in that the source(s) for the forming of the top electrode(s) is/are operated at a higher base pressure than the source(s) for the forming of organic layer(s).

13. A method in accordance with claim 10, characterized in that at least one source for the forming of the top electrode(s) is pivoted on the coating.

14. A method in accordance with claim 10, characterized in that a plurality of light emitting elements are formed arranged discretely with respect to one another on a substrate.

15. An apparatus in accordance with claim 2, characterized in that:
the source(s) for the deposition of the top electrode has/have a higher base pressure than the base pressure of at least one source for the forming of organic layers;
the substrate and the shadow mask are guided in a translatory manner through a continuous vacuum coating plant in which one or more source(s) for the forming of top electrodes is/are arranged sequentially in the direction of movement at one or more source(s) for organic layer(s);
the spacing between the substrate and the shadow mask is variable on the translatory movement;
evaporated organic compounds are directed at least almost orthogonally through the shadow mask onto the substrate;
at least one tilted or pivotable source for the forming of top electrode(s) is provided;
the source(s) for the forming of the top electrode is/are a thermal evaporator source, a PVD source and/or a CVD source; and
the at least one source for the forming of organic layer(s) is a thermal evaporator source.

16. A method in accordance with claim 11, characterized in that:
the source(s) for the forming of the top electrode(s) is/are operated at a higher base pressure than the source(s) for the forming of organic layer(s);
at least one source for the forming of the top electrode(s) is pivoted on the coating; and
a plurality of light emitting elements are formed arranged discretely with respect to one another on a substrate.
